(19) United States
(12) Patent Application Publication
(10) Pub. No.: US 2026/0314047 A1
(43) Pub. Date: Oct. 8, 2026

(54) STACKED FET WITH DIELECTRIC SPACER BETWEEN GATE METAL AND SOURCE/DRAIN CONTACT

(71) Applicant: INTERNATIONAL BUSINESS MACHINES CORPORATION, Armonk, NY (US)

(72) Inventors: Debarghya Sarkar, Latham, NY (US); Ruilong Xie, Niskayuna, NY (US); Lijuan Zou, Albany, NY (US); Junli Wang, Slingerlands, NY (US)

(21) Appl. No.: 19/172,007

(22) Filed: Apr. 7, 2025

(51) Int. Cl. H10D 84/83; H10D 30/00; H10D 30/01; H10D 30/43; H10D 62/10; H10D 64/23; H10D 64/27; H10D 84/01

(52) U.S. Cl. CPC H10D 84/832; H10D 30/014; H10D 30/019; H10D 30/43; H10D 30/502; H10D 62/116; H10D 62/121; H10D 64/251; H10D 64/516; H10D 84/0149; H10D 84/8311; H10D 84/83138

(57) ABSTRACT

Embodiments of present invention provide a semiconductor structure. The semiconductor structure includes a semiconductor transistor on top of a substrate, the semiconductor transistor having a metal gate between a source region and a drain region, the metal gate having a top portion of a first length and a bottom portion of a second length measured in a direction from the source region to the drain region, wherein the first length of the top portion is shorter than the second length of the bottom portion. A method of forming the same is also provided.

### BACKGROUND

The present application relates to manufacturing of semiconductor integrated circuits. More particularly, it relates to forming source/drain contact in a high aspect ratio area between metal gates and the structure formed thereby.

As semiconductor industry moves towards smaller node, field-effect-transistors (FETs) are aggressively scaled to fit into reduced footprint or real estate such as by the introduction of nanosheet transistors (NSFETs). Moreover, nanosheet transistors may be stacked together to further reduce the overall footprint and increase density of transistors.

In order to reach the bottom FET in a stacked FET structure, source/drain (S/D) contact to the epitaxial source/drain region have to be made through canyons of high aspect ratio, resulting in a highly narrowed down contact area and consequently high contact resistance. In the meantime, the presence of complex interlayer dielectric (ILD) structure in the current stacked FET as well as attempts tried to increase contact area at the epi interface also cause top contact dimension to flare, which is often associated with increased chance of short to the adjacent gate metal.

### SUMMARY

Embodiments of present invention provide a semiconductor structure. The semiconductor structure includes a semiconductor transistor on top of a substrate, the semiconductor transistor having a metal gate between a first source/drain region and a second source/drain region, the metal gate having a top portion of a first length and a bottom portion of a second length measured in a direction from the first source/drain region to the second source/drain region, wherein the first length of the top portion is shorter than the second length of the bottom portion.

According to one embodiment, the semiconductor structure further includes a dielectric spacer directly on top of the bottom portion of the metal gate, wherein a first sidewall of the dielectric spacer is vertically aligned with a first sidewall of the bottom portion of the metal gate; a second sidewall of the dielectric spacer is adjacent to a first sidewall of the top portion of the metal gate; and a second sidewall of the top portion of the metal gate is vertically aligned with a second sidewall of the bottom portion of the metal gate.

According to another embodiment, the semiconductor structure further includes a first sidewall spacer adjacent to the first sidewall of the dielectric spacer and the first sidewall of the bottom portion of the metal gate, and a second sidewall spacer adjacent to the second sidewall of the top portion of the metal gate and the second sidewall of the bottom portion of the metal gate.

In one embodiment, the semiconductor transistor is a first nanosheet transistor and the semiconductor structure further includes a second nanosheet transistor vertically on top of a portion of the first nanosheet transistor, where a width of nanosheets of the second nanosheet transistor is narrower or less than a width of nanosheets of the first nanosheet transistor.

According to one embodiment, the semiconductor structure further includes a first source/drain contact in contact with a first source/drain region of the first nanosheet transistor, the first source/drain contact being horizontally next to, and insulated from, a third source/drain region of the second nanosheet transistor.

In one embodiment, the first source/drain contact has a width measured in the direction from the first source/drain region to the second source/drain region, and the width decreases from a top to a bottom of the first source/drain contact.

In another embodiment, the first source/drain contact has a T-shaped cross-sectional area with a horizontal portion on top of a vertical portion, where the horizontal portion of the first source/drain contact extends into a dielectric spacer next to the top portion of the metal gate, and wherein the vertical portion of the first source/drain contact is at least partially separated from the dielectric spacer by a first sidewall spacer of the metal gate.

In one embodiment, the semiconductor transistor is a first nanosheet transistor and the metal gate is a first metal gate, and the semiconductor structure further includes a second nanosheet transistor on top of the substrate, where the second nanosheet transistor has a second metal gate and the second metal gate has a height that is substantially same as a height of the bottom portion of the first metal gate, the second nanosheet transistor sharing the first or the second source/drain region with the first nanosheet transistor.

According to one embodiment, the semiconductor structure further includes a dielectric spacer directly on top of the bottom portion of the first metal gate, where a first sidewall of the dielectric spacer is vertically aligned with a first sidewall of the bottom portion of the first metal gate; a second sidewall of the dielectric spacer is adjacent to a first sidewall of the top portion of the first metal gate; and a second sidewall of the top portion of the first metal gate is vertically aligned with a second sidewall of the bottom portion of the first metal gate.

According to another embodiment, the semiconductor structure further includes a dielectric stud on top of the second metal gate of the second nanosheet transistor, where a height of the dielectric stud is substantially same as a height of the dielectric spacer and substantially same as a height of the top portion of the first metal gate.

Embodiments of present invention further provide a method of forming a semiconductor structure. The method includes forming, on top of a substrate, a first and a second nanosheet transistor having a first and a second metal gate respectively; creating a recess in the first metal gate thereby creating a top portion and a bottom portion of the first metal gate, with the recess being adjacent to the top portion and above the bottom portion of the first metal gate; forming a dielectric spacer in the recess with a dielectric material; creating a contact opening above a first source/drain region of the first nanosheet transistor; and forming a source/drain contact in the contact opening in contact with the first source/drain region of the first nanosheet transistor, the dielectric spacer being between the source/drain contact and the top portion of the first metal gate.

In one embodiment, creating the contact opening includes removing a portion of a sidewall spacer and a horizontal portion of the dielectric spacer adjacent to the removed portion of the sidewall spacer.

In another embodiment, creating the recess further includes lowering a height of the second metal gate to be substantially same as a height of the bottom portion of the first metal gate.

According to one embodiment, the method further includes, after lowering the height of the second metal gate, forming a dielectric stud above the second metal gate of the second nanosheet transistor.

According to another embodiment, the method further includes forming a third and a fourth nanosheet transistor on top of the first and the second nanosheet transistor respectively, wherein a width of nanosheets of the third nanosheet transistor is narrower or less than a width of nanosheets of the first nanosheet transistor.

In one embodiment, forming the source/drain contact includes forming the source/drain contact horizontally adjacent to, and insulated from, a source/drain region of the third nanosheet transistor.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B are demonstrative illustrations of cross-sectional views of a semiconductor structure at a step of manufacturing thereof according to one embodiment of present invention;

FIGS. 2A and 2B are demonstrative illustrations of cross-sectional views of a semiconductor structure at a step of manufacturing thereof, following the step illustrated in FIGS. 1A and 1B, according to one embodiment of present invention;

FIGS. 3A and 3B are demonstrative illustrations of cross-sectional views of a semiconductor structure at a step of manufacturing thereof, following the step illustrated in FIGS. 2A and 2B, according to one embodiment of present invention;

FIGS. 4A and 4B are demonstrative illustrations of cross-sectional views of a semiconductor structure at a step of manufacturing thereof, following the step illustrated in FIGS. 3A and 3B, according to one embodiment of present invention;

FIGS. 5A and 5B are demonstrative illustrations of cross-sectional views of a semiconductor structure at a step of manufacturing thereof, following the step illustrated in FIGS. 4A and 4B, according to one embodiment of present invention;

FIGS. 6A and 6B are demonstrative illustrations of cross-sectional views of a semiconductor structure at a step of manufacturing thereof, following the step illustrated in FIGS. 5A and 5B, according to one embodiment of present invention;

FIGS. 7A and 7B are demonstrative illustrations of cross-sectional views of a semiconductor structure at a step of manufacturing thereof, following the step illustrated in FIGS. 6A and 6B, according to one embodiment of present invention;

FIGS. 8A and 8B are demonstrative illustrations of cross-sectional views of a semiconductor structure at a step of manufacturing thereof, following the step illustrated in FIGS. 7A and 7B, according to one embodiment of present invention;

FIGS. 9A and 9B are demonstrative illustrations of cross-sectional views of a semiconductor structure at a step of manufacturing thereof, following the step illustrated in FIGS. 8A and 8B, according to one embodiment of present invention;

FIGS. 10A and 10B are demonstrative illustrations of cross-sectional views of a semiconductor structure at a step of manufacturing thereof, following the step illustrated in FIGS. 9A and 9B, according to one embodiment of present invention;

FIGS. 11A and 11B are demonstrative illustrations of cross-sectional views of a semiconductor structure at a step of manufacturing thereof, following the step illustrated in FIGS. 10A and 10B, according to one embodiment of present invention;

FIGS. 12A and 12B are demonstrative illustrations of cross-sectional views of a semiconductor structure at a step of manufacturing thereof, following the step illustrated in FIGS. 11A and 11B, according to one embodiment of present invention;

FIGS. 13A and 13B are demonstrative illustrations of cross-sectional views of the semiconductor structure illustrated in FIGS. 12A and 12B;

FIG. 14 is a demonstrative illustration of an expanded cross-sectional view of the semiconductor structure illustrated in FIG. 12B; and

FIG. 15 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms "about" or "substantially" as used herein with regard to thicknesses, widths, percentages, ranges, etc., are meant to denote being close or approximate to, but not exactly. For example, the term "about" or "substantially" as used herein implies that a small margin of error may be present such as, by way of example only, 1% or less than the stated amount. Likewise, the terms "on", “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

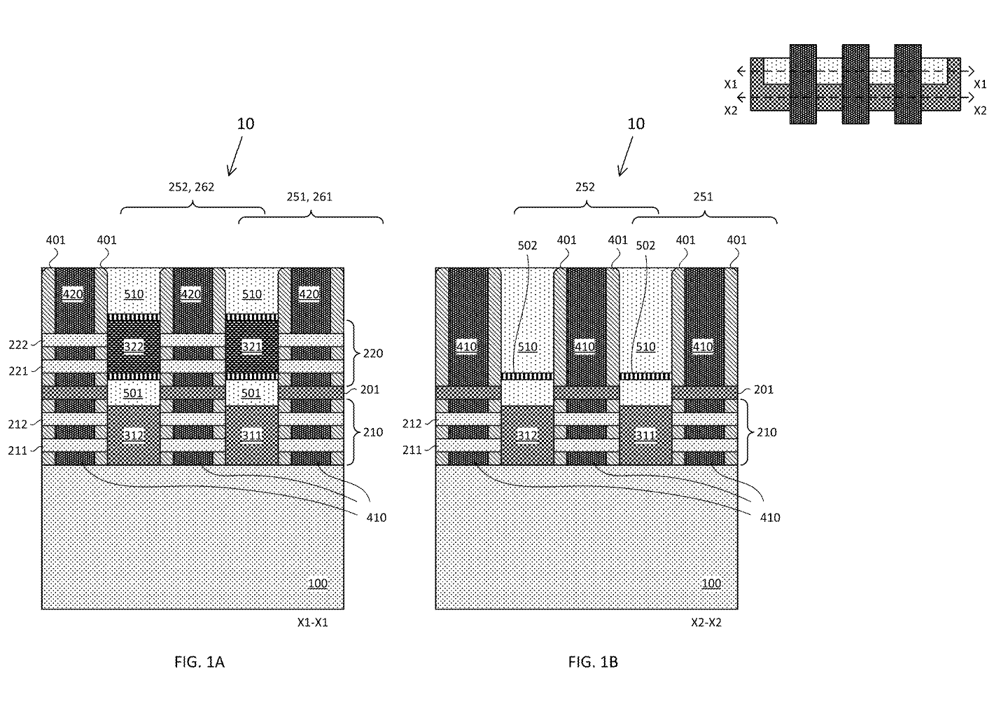

FIGS. 1A and 1B are demonstrative illustrations of different cross-sectional views of a semiconductor structure in a step of manufacturing thereof according to one embodiment of present invention. More specifically, FIG. 1A illustrates a cross-sectional view of a semiconductor structure 10 with a cross-section made along a dashed line X1-X1 as indicated in a simplified top view of the structure at the upper right corner of the drawing. In other words, the cross-section in FIG. 1A is made across a set of stacked FETs, both top FETs and bottom FETs, and across gates of the set of stacked FETs in a direction along a length of the gates, i.e., from a first source/drain region to a second source/drain region of a FET. FIG. 1B illustrates a cross-sectional view of the semiconductor structure 10 with a cross-section made along a dashed line X2-X2 as indicated in the same simplified top view of the structure. In other words, the cross-section in FIG. 1B is made across only the bottom FETs of the set of stacked FETs, and across the gates of the bottom FETs in a direction along the length of the gates.

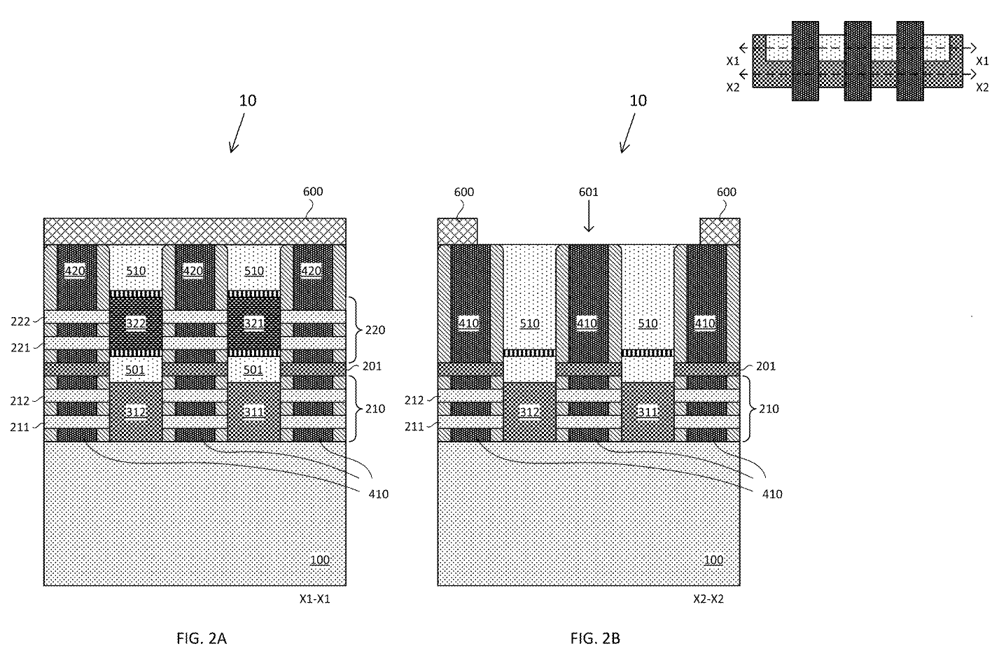

Likewise, FIGS. 2A and 2B - 12A and 12B are demonstrative cross-sectional views of the semiconductor structure 10, at different manufacturing steps, illustrated in manners similar to FIGS. 1A and 1B, respectively.

Embodiments of present invention provide forming the semiconductor structure 10 that is demonstratively illustrated in FIGS. 1A and 1B to include a set of stacked FETs. In one embodiment, the set of stacked FETs may be a set of stacked nanosheet transistors or more specifically nanosheet field-effect-transistors (NSFETs). It is noted there that embodiments of present invention are not limited in this aspect and may be applied to other types of transistors and/or active devices. The set of stacked FETs may be formed on top of a semiconductor substrate 100. The semiconductor substrate 100 may be, for example, a bulk silicon (Si) substrate, a bulk germanium (Ge) substrate, a bulk silicon-germanium (SiGe) substrate, a silicon-on-insulator (SOI) substrate, or a stack of semiconductor and/or insulator layers.

As is illustrated, the set of stacked FETs may include a set of top FETs 220 formed above a set of bottom FETs 210. The set of bottom FETs 210 may include, for example, a first bottom FET 251 and a second bottom FET 252. The first and second bottom FETs 251 and 252 may each include one or more nanosheets 211 and 212 and a metal gate 410 surrounding the one or more nanosheets 211 and 212; and may include a first source/drain region 311 and a second source/drain region 312 epitaxially formed at sidewalls of the one or more nanosheets 211 and 212. Sidewall spacers 401 and inner spacers may be formed at sidewalls of the metal gate 410. The set of top FETs 220 may include, for example, a first top FET 261 and a second top FET 262. The first and second top FETs 261 and 262 may each include one or more nanosheets 221 and 222 and a metal gate 420 surrounding the one or more nanosheets 221 and 222; and may include a first source/drain region 321 and a second source/drain region 322 epitaxially formed at sidewalls of the one or more nanosheets 221 and 222. Sidewall spacers 401 and inner spacers may be formed at sidewalls of the metal gate 420 as well.

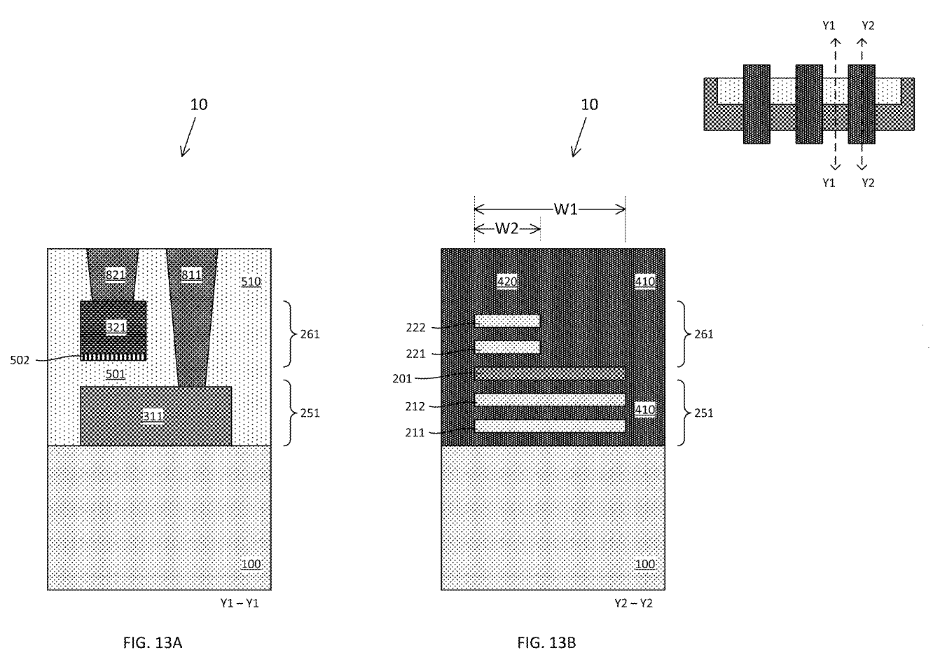

In one embodiment, the one or more nanosheets 211 and 212 of the set of bottom FETs 210 may have a first width W1, in a direction extending into and out of the drawing and the one or more nanosheets 221 and 222 of the set of top FETs 220 may have a second width W2, in a direction extending into and out of the drawing as well (see FIG. 13B). The second width W2 may be narrower or less than the first width W1. The metal gates 410 and 420 of the first bottom FET 251 and the first top FET 261 may be connected and share a same metal gate. The metal gates 410 and 420 of the second bottom FET 252 and the second top FET 262 may be connected and share a same metal gate as well. It is to be noted here that embodiments of present invention are not limited in this aspect and metal gates of the bottom and top FETs may not be connected and in some embodiments may be insulated from each other.

The first and second source/drain regions 321 and 322 of the set of top FETs 220, formed at end surfaces of the one or more nanosheets 221 and 222, may be vertically above only a portion of the first and second source/drain regions 311 and 312 of the set of bottom FETs 210, formed at end surfaces of the one or more nanosheets 211 and 212 (see FIG. 13A). As a result, the first and second source/drain regions 311 and 312 of the set of bottom FETs 210 may be accessed, such as by a source/drain contact, through the ILD layers 501 and 510 and the dielectric layer 502 without being blocked by the first and second source/drain regions 321 and 322 of the set of top FETs 220 (see FIG. 13A).

The first and second source/drain regions 311 and 312 of the set of bottom FETs 210 may be insulated from the first and second source/drain regions 321 and 322 of the set of top FETs 220 by an ILD layer 501. The first and second source/drain regions 321 and 322 may additionally be surrounded by a dielectric layer 502, which may be used an etch-stop layer in a subsequent processing step and may be covered at a top thereof by another ILD layer 510. The ILD layers 501 and 510, the dielectric layer 502, and the sidewall spacers 401 may be made of dielectric materials such as, for example, silicon-oxide (SiOx), silicon-nitride (SiN), silicon-carbide (SiC), silicon-oxycarbide (SiOC), silicon-oxycarbonitride (SiOCN), silicon-carbonitride (SiCN), or other suitable dielectric materials and may be made of the same or different materials. For example, material of the sidewall spacers 401 and the dielectric layer 502 may be SiN, and material of the ILD layers 501 and 510 may be SiOx.

FIGS. 2A and 2B are demonstrative illustrations of different cross-sectional views of the semiconductor structure 10 in a step of manufacturing thereof, following the step illustrated in FIGS. 1A and 1B, according to one embodiment of present invention. More particularly, embodiments of present invention provide forming a mask 600, such as forming a mask of organic planarization layer (OPL) through a lithographic patterning process, on top of the semiconductor structure 10. The mask 600 covers the set of top FETs 220 and includes an opening 601 that exposes a portion of the set of bottom FETs 210.

It is noted here that the metal gates 420 of the set of top FETs 220 may have a width, in a direction extending into and out of the drawing, that expand over a portion of the metal gates 410 of the set of bottom FETs 210. The mask 600 may be patterned such that it covers the metal gates 420 of the set of top FETs 220 that are on top of a first portion of the set of bottom FETs 210. The mask 600 has an opening 601 that leaves the metal gates 410 above a second portion of the set of bottom FETs 210 uncovered or exposed for subsequent processing.

In a horizontal direction, the opening 601 may expose a portion (i.e., a portion of a length) of the metal gate 410 of one bottom FET such as the first bottom FET 251 in one embodiment. In another embodiment, the opening 601 may additionally expose a full length of the metal gate 410 of another bottom FET such as the second bottom FET 252 that neighbors the first bottom FET 251. In yet another embodiment, the opening 601 may further expose a portion of the metal gate 410 of a third bottom FET that neighbors the second bottom FET 252.

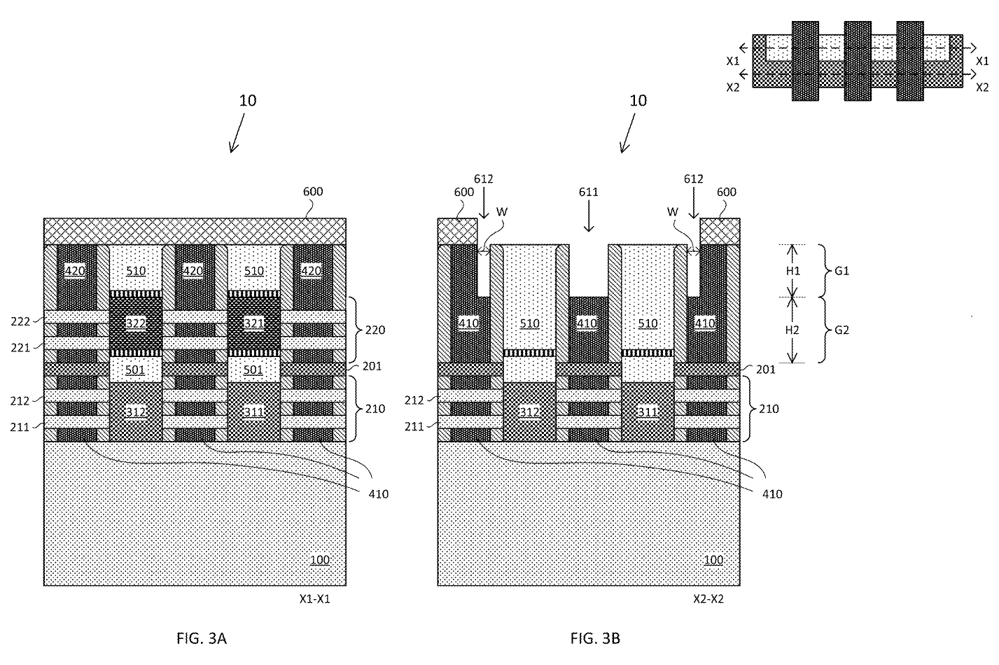

FIGS. 3A and 3B are demonstrative illustrations of different cross-sectional views of the semiconductor structure 10 in a step of manufacturing thereof, following the step illustrated in FIGS. 2A and 2B, according to one embodiment of present invention. More particularly, embodiments of present invention provide performing a selective etching process of removing a vertical portion of the exposed, and/or a vertical portion of the exposed portion of, metal gates 410 of the set of bottom FETs 210. For example, in one embodiment, the selective etching process may remove, selective to the ILD layer 510 and the sidewall spacers 401, a vertical portion of an exposed portion of a first metal gate 410 of the first bottom FET 251 thereby creating a recess 612 or opening. In another embodiment, the selective etching process may remove a vertical portion of a full length of a second metal gate 410 of the second bottom FET 252 thereby creating a recess 611 or opening.

The selective etching process thereby creates a top portion G1, with a height H1, and a bottom portion G2, with a height H2, of the first metal gate 410 of the first bottom FET 251. The recess 612 may have a width W, as being illustrated in FIG. 3B, resulting in a length of the top portion G1 being less than a length of the bottom portion G2 of the first metal gate 410 of the first bottom FET 251. On the other hand, the recess 611 above the second metal gate 410 of the second bottom FET 252 may have a height H2 that is substantially same as that of the bottom portion G2 of the first metal gate 410 of the first bottom FET 251.

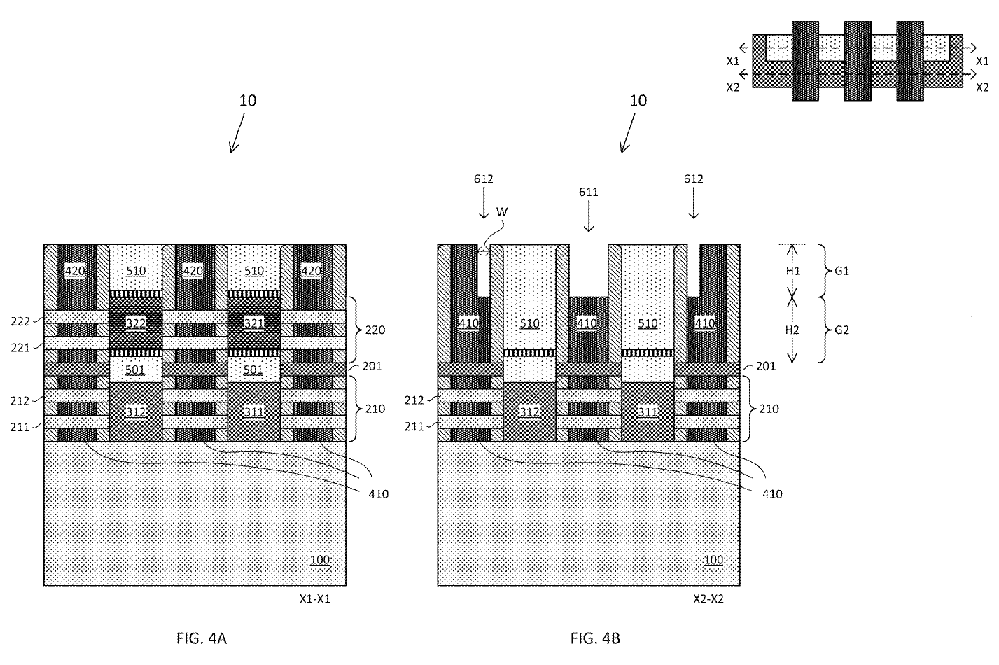

FIGS. 4A and 4B are demonstrative illustrations of different cross-sectional views of the semiconductor structure 10 in a step of manufacturing thereof, following the step illustrated in FIGS. 3A and 3B, according to one embodiment of present invention. More particularly, embodiments of present invention provide removing the mask 600 of OPL, thereby exposing the top portion G1 of the metal gates 410 of the set of bottom FETs 210 and the metal gates 420 of the set of top FETs 220 that are above portions of the set of bottom FETs 210. It is to be noted here that the mask 600 may be removed optionally at this stage and in one embodiment may be removed later after the formation of a dielectric stud and/or a dielectric spacer in the recess 611 and/or recess 612, as being described below in more details. The removal of the mask 600 may be made in an ash process.

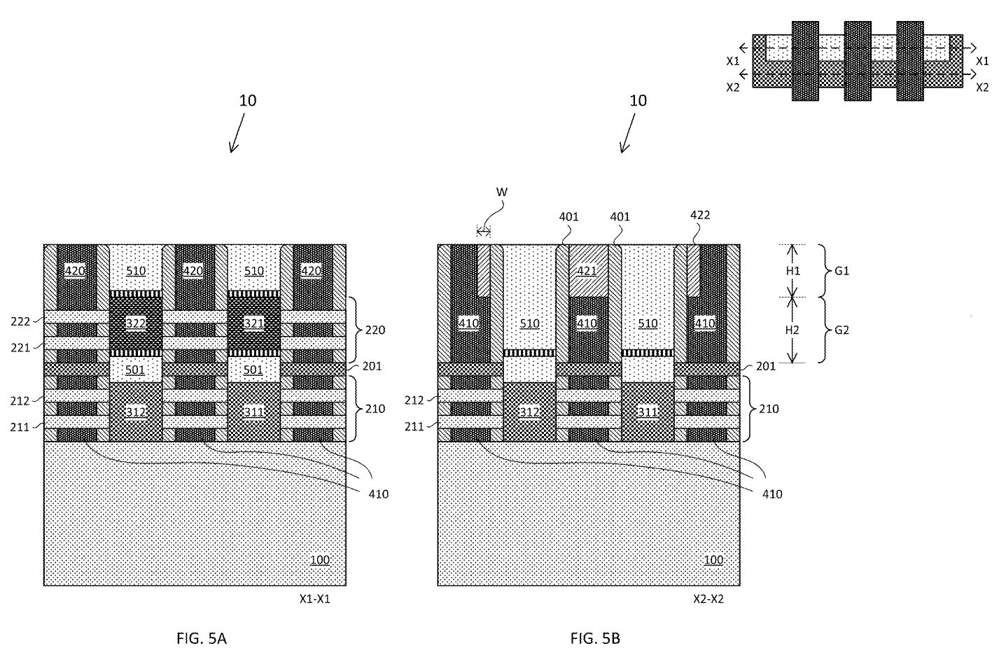

FIGS. 5A and 5B are demonstrative illustrations of different cross-sectional views of the semiconductor structure 10 in a step of manufacturing thereof, following the step illustrated in FIGS. 4A and 4B, according to one embodiment of present invention. More particularly, embodiments of present invention provide filling the recesses 611 and 612 with a dielectric material, or one or more dielectric materials, thereby forming a dielectric stud 421 and one or more dielectric spacers 422. For example, the dielectric stud 421 and/or the dielectric spacer 422 may be formed through a dielectric deposition process such as, for example, an atomic layer deposition (ALD) process, a chemical vapor deposition (CVD) process, and/or a physical vapor deposition (PVD) process, which is then followed by a chemical mechanical polishing (CMP) process to planarize a top surface of the dielectric stud 421 and/or the dielectric spacer 422.

The dielectric stud 421 may be formed to have a height H1 and fully cover the metal gate 410 of, for example, the second bottom FET 252. The dielectric spacer 422 may be formed to have a width W and a height H1 and directly adjacent to a sidewall of the top portion G1 and on top of the bottom portion G2 of the metal gate 410 of, for example, the first bottom FET 251. The top portion G1 of the metal gate 410 may have a first length and the bottom portion G2 of the metal gate 410 may have a second length, both of which are measured in a direction from the first source/drain region 311 to the second source/drain region 312, and the first length is shorter than the second length.

In one embodiment, the dielectric spacer 422 is adjacent to the top portion G1 and directly on top of the bottom portion G2 of the metal gate 410 of the first bottom FET 251. A first (or left) sidewall of the dielectric spacer 422 is vertically aligned with a first (or left) sidewall of the bottom portion G2 of the metal gate 410; a second (or right) sidewall of the dielectric spacer 422 is adjacent to a first (or left) sidewall of the top portion G1 of the metal gate 410; and a second (or right) sidewall of the top portion G1 of the metal gate 410 is vertically aligned with a second (or right) sidewall of the bottom portion G2 of the metal gate 410.

In a further embodiment, a sidewall spacer 401 is adjacent to the first (or left) sidewall of the dielectric spacer 422 and the first (or left) sidewall of the bottom portion G2 of the metal gate 410, and another sidewall spacer 401 is adjacent to the second (or right) sidewall of the top portion G1 of the metal gate 410 and the second (or right) sidewall of the bottom portion G2 of the metal gate 410.

The dielectric stud 421 and/or the dielectric spacer 422 may be made of SiOx, SiN, SiC, SiOC, SiOCN, SiCN, or other suitable materials and may be materially same or different from those of the sidewall spacers 401. For example, in one embodiment, the dielectric stud 421, the dielectric spacer 422, and the sidewall spacers 401 may all be made of SiN.

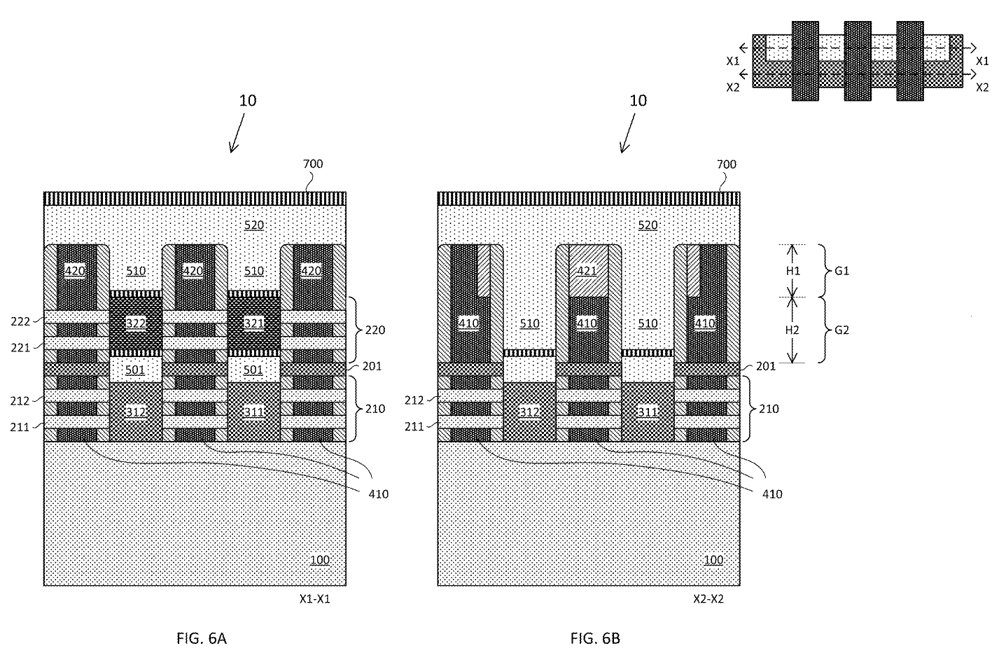

FIGS. 6A and 6B are demonstrative illustrations of different cross-sectional views of the semiconductor structure 10 in a step of manufacturing thereof, following the step illustrated in FIGS. 5A and 5B, according to one embodiment of present invention. More particularly, embodiments of present invention provide forming a middle-of-line (MOL) ILD layer 520 on top of the structure including on top of the dielectric stud 421, the dielectric spacer 422, the top portion G1 of the metal gate 410, the metal gate 420, and the ILD layer 510. Embodiments of present invention may subsequently form a hard mask layer 700 on top of the ILD layer 520, which may be used in an etching process of the ILD layers 510 and 520 in forming source/drain (S/D) contacts as being described below in more details.

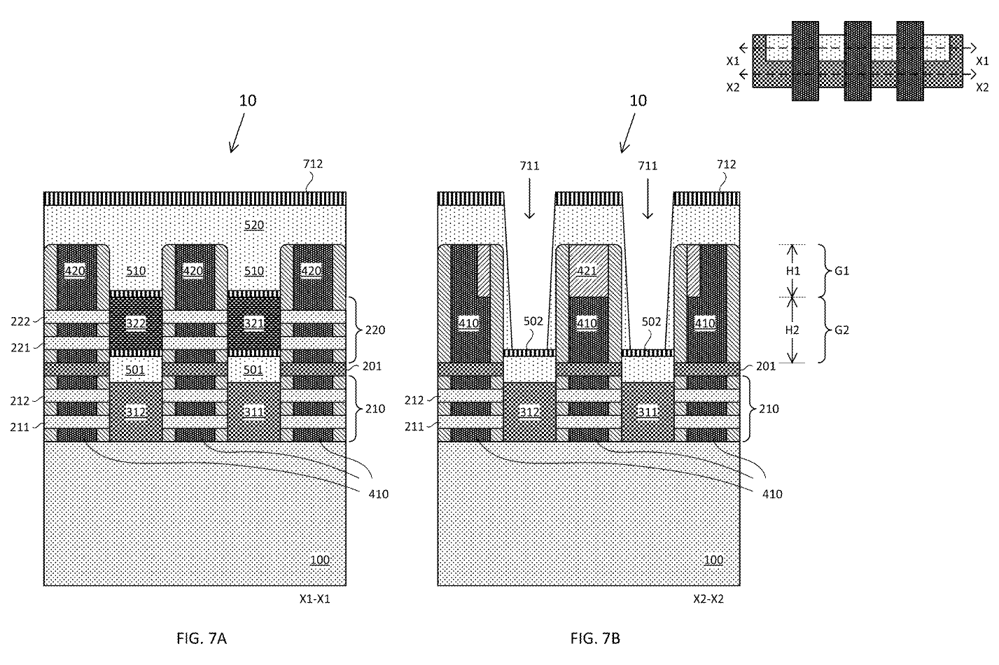

FIGS. 7A and 7B are demonstrative illustrations of different cross-sectional views of the semiconductor structure 10 in a step of manufacturing thereof, following the step illustrated in FIGS. 6A and 6B, according to one embodiment of present invention. More particularly, embodiments of present invention provide forming a hard mask 712, with openings 711, from the hard mask layer 700 and extending the openings 711 in the ILD layer 520 and the ILD layer 510 underneath the ILD layer 520 that is between the metal gates 410 through an etching process. In one embodiment, the etching process may be selective to the material of the ILD layers 510 and 520, and the dielectric layer 502 underneath the ILD layer 510 may serve as an etch-stop layer.

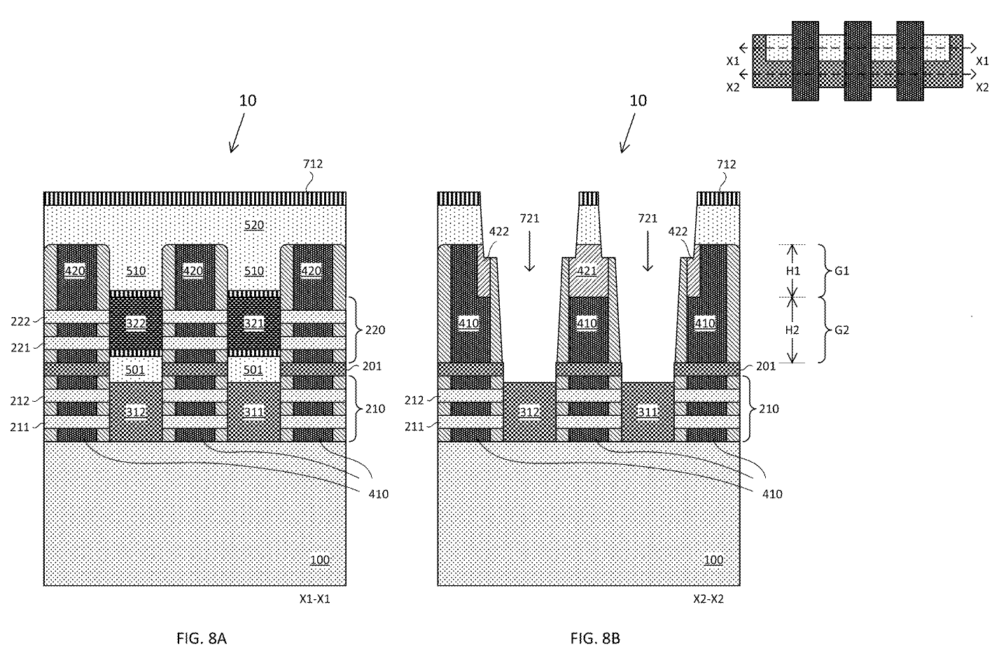

FIGS. 8A and 8B are demonstrative illustrations of different cross-sectional views of the semiconductor structure 10 in a step of manufacturing thereof, following the step illustrated in FIGS. 7A and 7B, according to one embodiment of present invention. More particularly, embodiments of present invention provide continuing etching the exposed dielectric layer 502, which may have different etch selectivity from the ILD layer 510 and 520. This etching further extends the openings 711 into the dielectric layer 502 and the ILD layer 501 underneath thereof, thereby creating contact openings 721 that may expose the source/drain regions 311 and 312 of the set of bottom FETs 210.

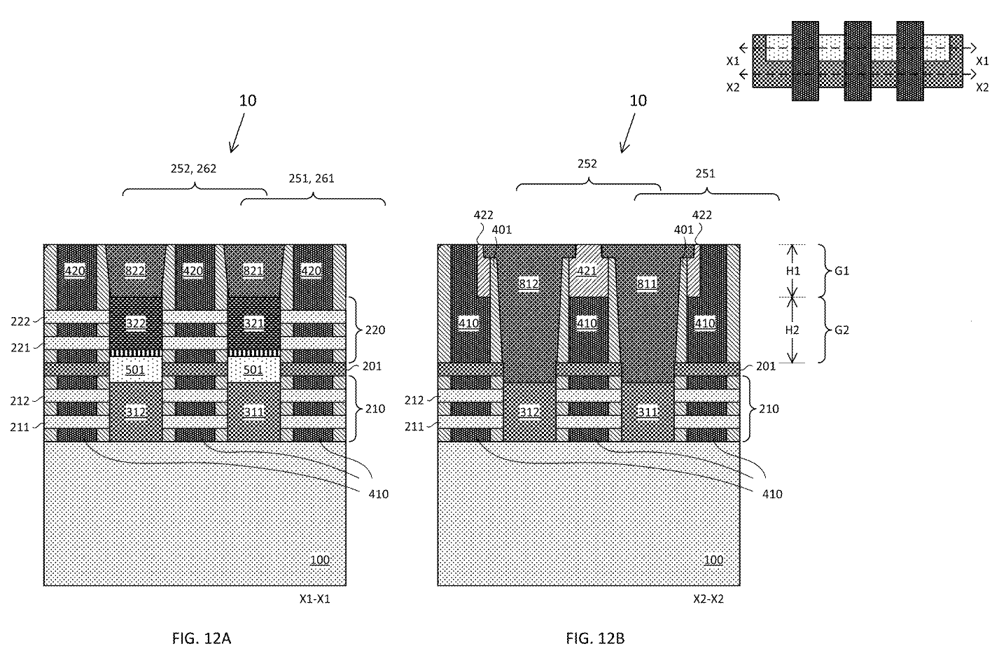

In one embodiment, etching to create the contact openings 721 may horizontally etch into the sidewall spacer 401 and may, in some embodiment, further etch into a portion of the dielectric spacer 422 and/or the dielectric stud 421. Such etching may be caused by, for example, etch erosion or may be done intentionally in order to reduce contact resistance of later formed source/drain contacts (see FIG. 12B). According to one embodiment of present invention, the use or creation of the dielectric spacer 422 enables the contact openings 721 to have a wider opening, whether caused by etch erosion or not, without exposing the metal gate 410 particularly the top portion G1 of the metal gate 410. Thereby, subsequently formed source/drain contacts in the contact openings 721 may be insulated from the metal gate 410 and avoidance of short may be achieved.

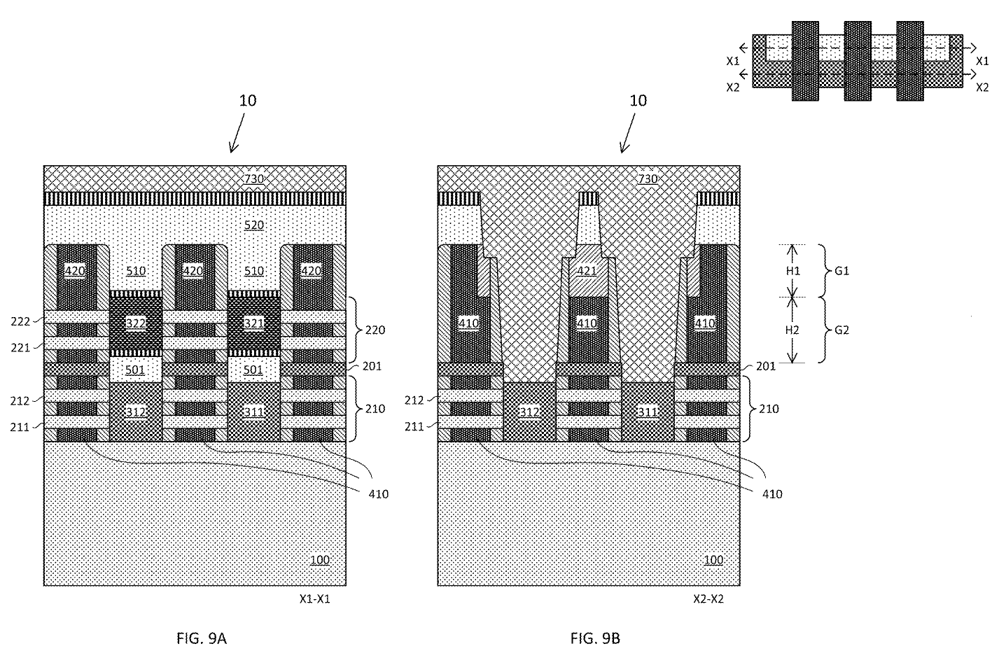

FIGS. 9A and 9B are demonstrative illustrations of different cross-sectional views of the semiconductor structure 10 in a step of manufacturing thereof, following the step illustrated in FIGS. 8A and 8B, according to one embodiment of present invention. More particularly, embodiments of present invention provide protecting the exposed source/drain regions 311 and 312 such that source/drain contact openings may be created for the set of top FETs 220. In doing so, embodiments of present invention provide depositing a layer of OPL layer 730 on top of the exposed source/drain regions 311 and 312, which completely fills the contact openings 721 to a level above the hard mask 712. A CMP process may subsequently be applied to planarize a top surface of the OPL layer 730.

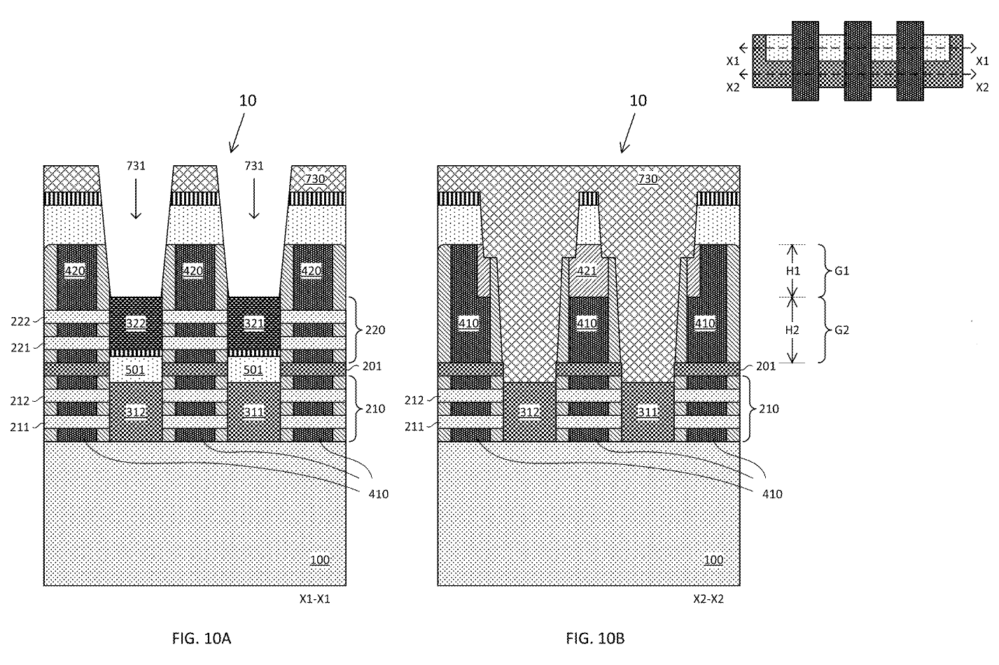

FIGS. 10A and 10B are demonstrative illustrations of different cross-sectional views of the semiconductor structure 10 in a step of manufacturing thereof, following the step illustrated in FIGS. 9A and 9B, according to one embodiment of present invention. More particularly, embodiments of present invention provide patterning the OPL layer 730 to create one or more openings and subsequently extending the openings through the ILD layers 520 and 510, in a selective etching process, to create one or more contact openings 731. The contact openings 731 expose source/drain regions 321 and 322 of the set of top FETs 220. In the meantime, rest of the OPL layer 730 may remain in the contact openings 721 protecting the source/drain regions 311 and 312 of the set of bottom FETs 210.

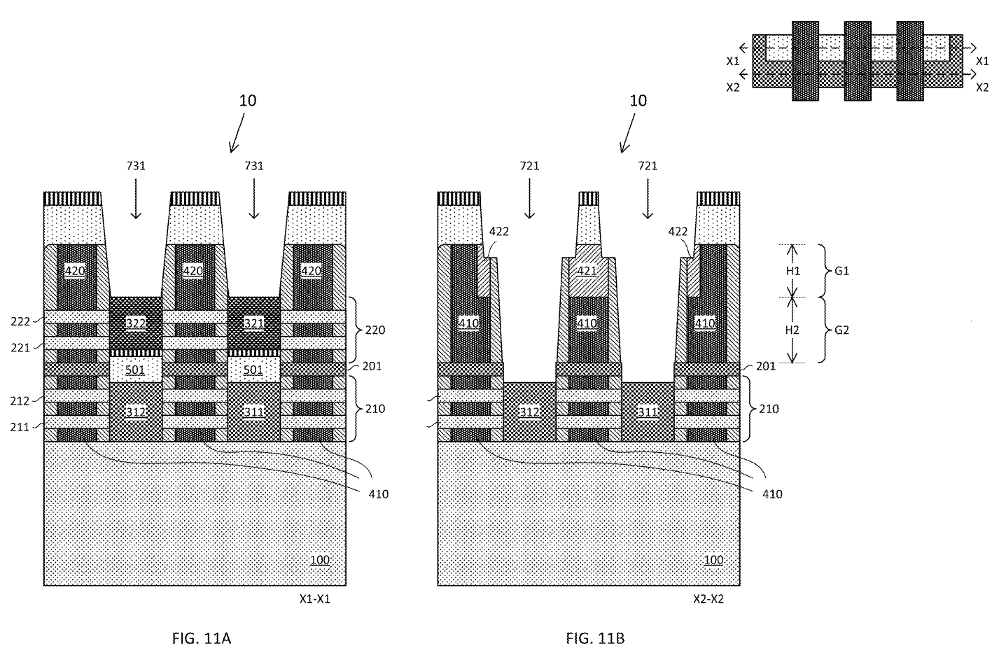

FIGS. 11A and 11B are demonstrative illustrations of different cross-sectional views of the semiconductor structure 10 in a step of manufacturing thereof, following the step illustrated in FIGS. 10A and 10B, according to one embodiment of present invention. More particularly, embodiments of present invention provide, following the creation of contact openings 731, the OPL layer 730 may be removed through a selective etching process such as, for example, an ash process.

FIGS. 12A and 12B are demonstrative illustrations of different cross-sectional views of the semiconductor structure 10 in a step of manufacturing thereof, following the step illustrated in FIGS. 11A and 11B, according to one embodiment of present invention. More particularly, embodiments of present invention provide forming source/drain contacts of both the set of top FETs 220 and the set of bottom FETs 210 through a metallization process. For example, same or different conductive materials may be deposited into and fill up the contact openings 721 for the set of bottom FETs 210, such as the first bottom FET 251 and the second bottom FET 252, and into contact openings 731 for the set of top FETs 220, such as the first top FET 261 and the second top FET 262. Subsequently, top surfaces of the conductive materials may be planarized through, for example, a CMP process. The CMP process may also remove the hard mask 712 and the ILD layer 520, thereby forming a first and a second source/drain contact 811 and 812 of the set of bottom FETs 210 and a first and a second source/drain contact 821 and 822 of the set of top FETs 220.

In one embodiment, because of the kink of the contact openings 721, the first and second source/drain contacts 811 and 812 may have a T-shaped cross-sectional area having a horizontal portion on top of a vertical portion. The horizontal portion extends partially into the dielectric spacer 422 that is next to the top portion G1 of the metal gate 410. The vertical portion, between the sidewall spacers 401 and in contact with the source/drain regions 311 and 312, is at least partially separated from the dielectric spacer 422 by the sidewall spacers 401. In one embodiment, the first and second source/drain contacts 811 and 812 may have a cross-sectional area whose width, measured in a direction between two metal gates 410 or from a first source/drain region to a second source/drain region, are not uniform. For example, the width of the first source/drain contact 811 may decrease from a top to a bottom of the first source/drain contact 811.

FIGS. 13A and 13B are demonstrative illustrations of different cross-sectional views of the semiconductor structure 10 illustrated in FIGS. 12A and 12B. More specifically, FIG. 13A illustrates a cross-sectional view of the semiconductor structure 10 with a cross-section made along a dashed line Y1-Y1, as indicated in the simplified top view, across source/drain regions of the set of stacked FETs in a direction along a width of the gates, i.e., along a width of the nanosheets. FIG. 13B illustrates a cross-sectional view of the semiconductor structure 10 with a cross-section made along a dashed line Y2-Y2, as indicated in the simplified top view, across gates of the set of stacked FETs in a direction along the width of the gates as well.

As is illustrated in FIG. 13A, the first source/drain region 321 of the first top FET 261 may be vertically above only a portion of the first source/drain region 311 of the first bottom FET 251 such that the first source/drain region 311 of the first bottom FET 251 may be contacted by the first source/drain contact 811 through the ILD layers 510 and 501. In other words, access to the first source/drain region 311 of the first bottom FET 251 is not blocked by the first source/drain region 321 of the first top FET 261. The first source/drain region 321 of the first top FET 261 is contacted by the second source/drain contact 821, whose access is available directly from a top thereof. In the meantime, the first source/drain region 311 of the first bottom FET 251 is insulated from the first source/drain region 321 of the first top FET 261 by the ILD layer 501 and, in some embodiment, by the dielectric layer 502. In one embodiment, the first source/drain contact 811 is in contact with the first source/drain region 311 of the first bottom FET 251 and horizontally next to, and insulated from, a first source/drain region 321 of the first top FET 261.

As is illustrated in FIG. 13B, the metal gate 410 of the first bottom FET 251 may be conductively connected to the metal gate 420 of the first top FET 261 by some conductive materials that surround the MDI 201. The one or more nanosheets 211 and 212 of the first bottom FET 251 may have a first width W1 and the one or more nanosheets 221 and 222 of the first top FET 261 may have a second width W2. In one embodiment, the second width W2 is narrower or less than the first width W1.

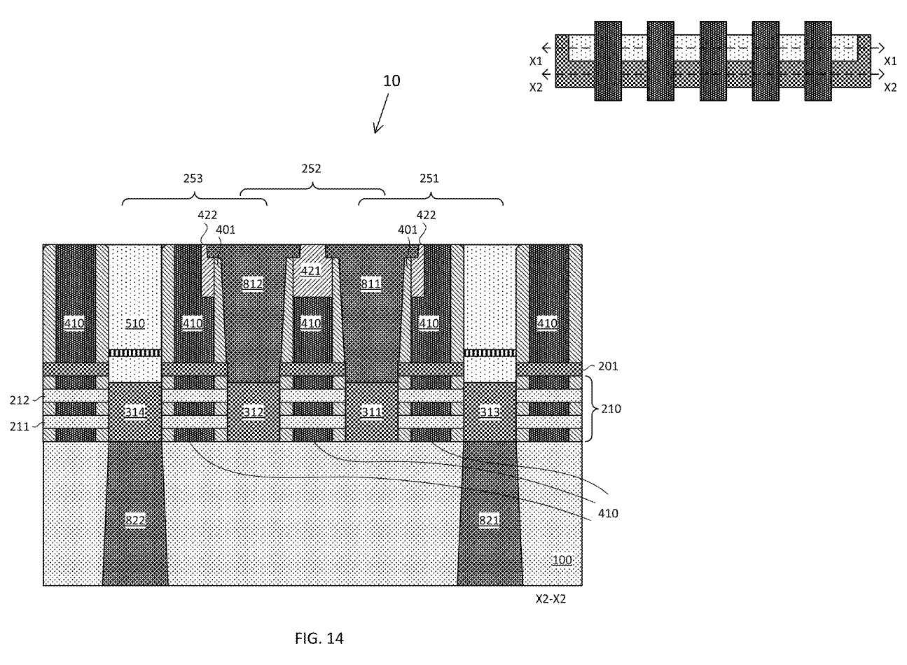

FIG. 14 is a demonstrative illustration of an expanded cross-sectional view of the semiconductor structure 10 illustrated in FIG. 12B. The semiconductor structure 10 may include the first and second bottom FETs 251 and 252 and a third bottom FET 253. The first source/drain contact 811 may contact the first source/drain region 311 and a third source/drain contact 821 may contact a third source/drain region 313 and the third source/drain contact 821 may be a backside contact formed from a backside of the semiconductor structure 10. The first source/drain region 311 and the third source/drain region 313 may be source/drain regions of the first bottom FET 251. On the other hand, the second bottom FET 252 may share the same first source/drain region 311 and the first source/drain contact 811 with the first bottom FET 251. The second source/drain contact 812 may contact the second source/drain region 312, which is a source/drain region of the second bottom FET 252 as well. The semiconductor structure 10 may include additional source/drain contacts, such as a fourth source/drain contact 822 contacting a fourth source/drain region 314, which is a source/drain region of the third bottom FET 253. The third bottom FET 253 may also share the same second source/drain region 312 and the same second source/drain contact 812 with the second bottom FET 252.

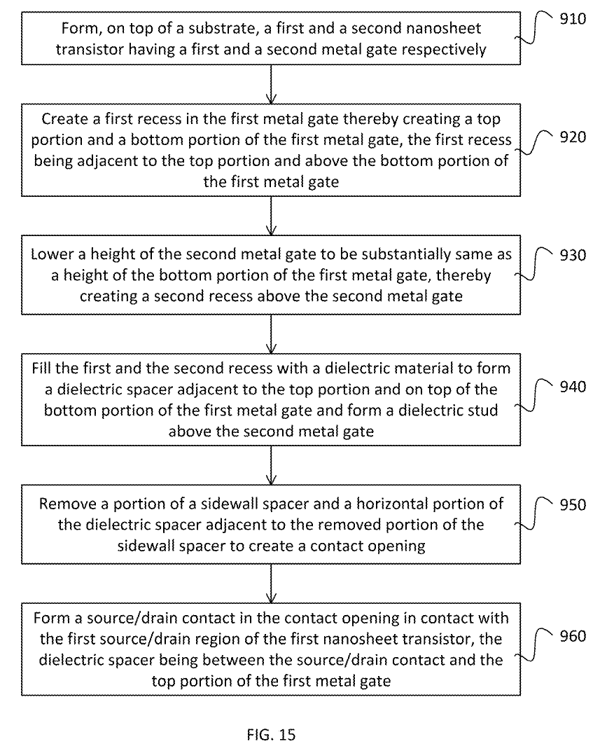

FIG. 15 is a demonstrative illustration of a flow-chart of a method of manufacturing a semiconductor structure according to embodiments of present invention. The method includes (910) forming, on top of a substrate, a first and a second nanosheet transistor having a first and a second metal gate respectively; (920) creating a first recess in the first metal gate thereby creating a top portion and a bottom portion of the first metal gate, the first recess being adjacent to the top portion and above the bottom portion of the first metal gate; (930) lowering a height of the second metal gate to be substantially same as a height of the second portion of the first metal gate, thereby creating a second recess above the second metal gate; (940) filling the first and the second recess with a dielectric material to form a dielectric spacer adjacent to the top portion and on top of the bottom portion of the first metal gate and form a dielectric stud above the second metal gate; (950) removing a portion of a sidewall spacer and a horizontal portion of the dielectric spacer adjacent to the removed portion of the sidewall spacer to create a contact opening; and (960) forming a source/drain contact in the contact opening in contact with the first source/drain region of the first nanosheet transistor, the dielectric spacer being between the source/drain contact and the top portion of the first metal gate.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a semiconductor transistor on top of a substrate, the semiconductor transistor having a metal gate between a first source/drain region and a second source/drain region, the metal gate having a top portion of a first length and a bottom portion of a second length measured in a direction from the first source/drain region to the second source/drain region, wherein the first length of the top portion is less than the second length of the bottom portion.

2. The semiconductor structure of claim 1, further comprising a dielectric spacer directly on top of the bottom portion of the metal gate, wherein a first sidewall of the dielectric spacer is vertically aligned with a first sidewall of the bottom portion of the metal gate; a second sidewall of the dielectric spacer is adjacent to a first sidewall of the top portion of the metal gate; and a second sidewall of the top portion of the metal gate is vertically aligned with a second sidewall of the bottom portion of the metal gate.

3. The semiconductor structure of claim 2, further comprising a first sidewall spacer adjacent to the first sidewall of the dielectric spacer and the first sidewall of the bottom portion of the metal gate, and a second sidewall spacer adjacent to the second sidewall of the top portion of the metal gate and the second sidewall of the bottom portion of the metal gate.

4. The semiconductor structure of claim 1, wherein the semiconductor transistor is a first nanosheet transistor, further comprising a second nanosheet transistor vertically on top of a portion of the first nanosheet transistor, wherein a width of nanosheets of the second nanosheet transistor is narrower than a width of nanosheets of the first nanosheet transistor.

5. The semiconductor structure of claim 4, further comprising a first source/drain contact in contact with a first source/drain region of the first nanosheet transistor, the first source/drain contact being horizontally adjacent to, and insulated from, a third source/drain region of the second nanosheet transistor.

6. The semiconductor structure of claim 5, wherein the first source/drain contact has a width measured in the direction from the first source/drain region to the second source/drain region, and the width decreases from a top to a bottom of the first source/drain contact.

7. The semiconductor structure of claim 5, wherein the first source/drain contact has a T-shaped cross-sectional area with a horizontal portion on top of a vertical portion, wherein the horizontal portion of the first source/drain contact extends into a dielectric spacer next to the top portion of the metal gate, and wherein the vertical portion of the first source/drain contact is at least partially separated from the dielectric spacer by a first sidewall spacer of the metal gate.

8. The semiconductor structure of claim 1, wherein the semiconductor transistor is a first nanosheet transistor and the metal gate is a first metal gate, the semiconductor structure further comprising:
a second nanosheet transistor on top of the substrate,
wherein the second nanosheet transistor has a second metal gate and the second metal gate has a height that is substantially same as a height of the bottom portion of the first metal gate, the second nanosheet transistor sharing the first or the second source/drain region with the first nanosheet transistor.

9. The semiconductor structure of claim 8, further comprising a dielectric spacer directly on top of the bottom portion of the first metal gate, wherein a first sidewall of the dielectric spacer is vertically aligned with a first sidewall of the bottom portion of the first metal gate; a second sidewall of the dielectric spacer is adjacent to a first sidewall of the top portion of the first metal gate; and a second sidewall of the top portion of the first metal gate is vertically aligned with a second sidewall of the bottom portion of the first metal gate.

10. The semiconductor structure of claim 9, further comprising a dielectric stud on top of the second metal gate of the second nanosheet transistor, wherein a height of the dielectric stud is substantially same as a height of the dielectric spacer and substantially same as a height of the top portion of the first metal gate.

11. The semiconductor structure of claim 8, further comprising a third nanosheet transistor vertically on top of a portion of the first nanosheet transistor, wherein a width of nanosheets of the third nanosheet transistor is narrower than a width of nanosheets of the first nanosheet transistor.

12. The semiconductor structure of claim 11, further comprising a first source/drain contact in contact with the first source/drain region, wherein the third nanosheet transistor has a third source/drain region, the first source/drain contact being horizontally next to, and insulated from, the third source/drain region of the third nanosheet transistor.

13. The semiconductor structure of claim 12, wherein the first source/drain contact has a width measured in the direction from the first source/drain region to the second source/drain region, and the width decreases from a top to a bottom of the first source/drain contact.

14. The semiconductor structure of claim 12, wherein the first source/drain contact has a T-shaped cross-sectional area with a horizontal portion on top of a vertical portion, wherein the horizontal portion of the first source/drain contact extends into a dielectric spacer on top of the bottom portion of the first metal gate of the first nanosheet transistor, and into a dielectric stud on top of the second metal gate of the second nanosheet transistor.

15. A method of forming a semiconductor structure comprising:
forming, on top of a substrate, a first and a second nanosheet transistor having a first and a second metal gate respectively;
creating a recess in the first metal gate thereby creating a top portion and a bottom portion of the first metal gate, with the recess being adjacent to the top portion and above the bottom portion of the first metal gate;
forming a dielectric spacer in the recess with a dielectric material;
creating a contact opening above a first source/drain region of the first nanosheet transistor; and
forming a source/drain contact in the contact opening in contact with the first source/drain region of the first nanosheet transistor, the dielectric spacer being between the source/drain contact and the top portion of the first metal gate.

16. The method of claim 15, wherein creating the contact opening comprises removing a portion of a sidewall spacer and a horizontal portion of the dielectric spacer adjacent to the portion of the sidewall spacer being removed.

17. The method of claim 15, wherein creating the recess further comprises lowering a height of the second metal gate to be substantially same as a height of the bottom portion of the first metal gate.

18. The method of claim 17, further comprising, after lowering the height of the second metal gate, forming a dielectric stud above the second metal gate of the second nanosheet transistor.

19. The method of claim 15, further comprising forming a third and a fourth nanosheet transistor on top of the first and the second nanosheet transistor respectively, wherein a width of nanosheets of the third nanosheet transistor is narrower than a width of nanosheets of the first nanosheet transistor.

20. The method of claim 19, wherein forming the source/drain contact comprises forming the source/drain contact horizontally adjacent to, and insulated from, a source/drain region of the third nanosheet transistor.
